(19) United States
(12) Patent Application Publication
(10) Pub. No.: US 2021/0036166 A1
(43) Pub. Date: Feb. 4, 2021

(54) MERGED PiN SCHOTTKY (MPS) DIODE WITH MULTIPLE CELL DESIGN AND MANUFACTURING METHOD THEREOF

(71) Applicants: Xiaotian Yu, LOS ANGELES, CA (US); Zheng Zuo, LOS ANGELES, CA (US); Ruigang Li, LOS ANGELES, CA (US)

(72) Inventors: Xiaotian Yu, LOS ANGELES, CA (US); Zheng Zuo, LOS ANGELES, CA (US); Ruigang Li, LOS ANGELES, CA (US)

(73) Assignee: AZ Power, Inc, CULVER CITY, CA (US)

(21) Appl. No.: 16/945,813

(22) Filed: Aug. 1, 2020

Related U.S. Application Data
(60) Provisional application No. 62/881,526, filed on Aug. 1, 2019.

(51) Int. Cl. H01L 29/872; H01L 29/868; H01L 29/66

(52) U.S. Cl. CPC H01L 29/872; H01L 29/66143; H01L 29/868

(57) ABSTRACT

A method for manufacturing a merged PiN Schottky (MPS) diode may include steps of providing a substrate having a first conductivity type; forming an epitaxial layer with the first conductivity type on top of the substrate; forming a plurality of regions with a second conductivity type under a top surface of the epitaxial layer; depositing and patterning a first Ohmic contact metal on the regions with the second conductivity type; depositing a Schottky contact metal on top of the entire epitaxial layer; and forming a second Ohmic contact metal on a backside of the substrate. In another embodiment, the step of forming a plurality of regions with a second conductivity type under a top surface of the epitaxial layer may include steps of depositing and patterning a mask layer on the epitaxial layer, implanting P-type dopant into the epitaxial layer, and removing the mask layer.

### CROSS-REFERENCE TO RELATED APPLICATIONS

This application claims priority under 35 U.S.C. § 119 (e) to U.S. Provisional Patent Application Ser. No. 62/881,526, filed on Aug. 1, 2019, the entire contents of which are hereby incorporated by reference.

### FIELD OF THE INVENTION

The present invention relates to a power diode structure, and more particularly to a merged PiN junction Schottky (MPS) diode with enhanced reliability under a surge current and a manufacturing method of making the MPS diode.

### BACKGROUND OF THE INVENTION

Power devices include power diodes and power switching transistors. Power diodes have two modes of operation in circuit applications, which are conduction mode and blocking mode. For the conduction mode, in addition to nominal current conditions, there is an occasional surge current condition. Under the abnormal conditions with surge current, the diode may have instant energy overshoot and chip temperature rise, resulting in device failure.

Power devices are expected to endure high current stresses under surges caused by circuit failure or lightning. Usually a great amount of energy, caused by high current multiplied by high voltage drop, flows into the device in quite a short time, leading to rapidly raised temperature and possibly a device failure. Surge capability is a key performance index which describes the robustness of power devices under extreme operating conditions. Devices with preeminent surge capability can dissipate such energy efficiently without a failure, thus offering a higher safety margin to the power system.

Silicon carbide semiconductor has two times larger bandgap compared with Silicon semiconductor. With a higher critical electric field, higher thermal conductivity, lower intrinsic carrier concentration, and higher saturation drift velocity, silicon carbide semiconductor has become an ideal candidate for high voltage, high temperature and high-power devices.

There are two technical routes for commercial devices based on silicon carbide power diodes, namely junction barrier Schottky (JBS) diode structure and merged PiN Schottky (MPS) diode structure.

For silicon carbide (SiC) materials, the Junction Barrier Schottky (JBS) diode is widely used. Armed with excellent characteristics of SiC material and characterized by alternatively arranged small P+ regions in N− drift layer, it has received large attention for its low forward voltage drop and low reverse leakage current. Merged PiN Schottky (MPS) diode was proposed based on the JBS diode structure, with merged large P+ regions into the active region. PN junctions formed by these large P+ regions will turn on under high current flows. Large amount of minority carriers will be injected into the drift layer, providing a lower resistivity and a higher current conduction capability. Thus, it offers higher surge capability compared to traditional JBS diode, as well as preserving a low forward voltage drop and reverse leakage current at the same time.

### SUMMARY OF THE INVENTION

In one aspect, a merged PiN Schottky (MPS) diode may include a silicon carbide substrate having a first conductivity type, an epitaxial layer with the first conductivity type formed on the substrate. In one embodiment, the doping concentration in the epitaxial layer is lower than that in the substrate. The merged PiN Schottky (MPS) diode may further include a plurality of regions having a second conductivity type different from the first conductivity type, and formed under a top surface of the epitaxial layer.

A first Ohmic contact metal is formed on top of each of the regions of the second conductivity type, and a Schottky contact metal is placed on top of the entire epitaxial layer to form a Schottky junction. A second Ohmic contact is formed by a cathode electrode on the back side of the substrate.

In one embodiment, the layout design of the merged PiN Schottky (MPS) diode can be a strip cell structure or hexagonal cell structure. Based on the hexagonal cell structure, the design can be extended to a composite structure of multiple cells by adding hexagonal cells with different sizes.

When the diode is under forward bias, current flows from the anode of the diode through the Schottky junction 16 into the drift region, then through the substrate layer and flows out of the cathode electrode. Before the current enters the drift region, it first passes through the channel region formed between the second conductivity type regions. Meanwhile, the current will form a potential difference on the PN junction, which is formed between the region with second conductivity type and the drift region with first conductivity type. When this potential difference exceeds the built-in potential of the PN junction, the PN junction will be turned on. Changing the width of the second conductivity type region will affect the threshold that triggers the turn-on of the PN junction. At the moment when the PN junction is turned on, the voltage drop between the anode and cathode of the diode is referred to as the PN junction turn-on voltage. The larger the width of the region of the second conductivity type, the lower the PN junction turn-on voltage. As shown in FIG. 4, the dash lines BB′, CC′ respectively show the current paths near the second conductivity type regions 14 with widths W₁ and W₂, respectively. When the potential difference between BB′ and CC′ reaches the built-in potential of the PN junction, the PN junction will be turned on. The potential difference between BB′ and CC′ is equal to the channel current times the resistance along the line BB′ and CC′, separately. It can be clearly seen from the figure that when the P+ region spacing is constant, the resistance of the channel is mainly affected by the width of the P+ region. If the width of the P+ region is larger (W₁ is greater than W₂), the resistance is larger (R_{BB′} is larger than R_{CC′}). Therefore, when the current increases to the threshold I₁ that triggers the first PN junction (FIG. 4, Structure 15A, formed by the P+ region with the width W₁), the potential difference between BB′ will reach the built-in potential of the PN junction, and the PN junction will be first turned on. As the current continues to increase and once the current is beyond the threshold I₂ at which the second PN junction is turned on, the potential difference between CC′ also reaches the built-in potential of the PN junction (FIG. 4, Structure 15B, formed by the P+ region of width W₂).

Based on the structure of the merged PiN Schottky (MPS) diode with the multiple cell proposed in this patent, the PN junction formed by different sizes of P+ regions are gradually turned on when the current exceeds the different corresponding threshold levels under the surge current. The electrical performance of the device under the surge current shock is closely related to the structure design. The device with two difference cells layout design having two different PN junctions, the wide PN junction (FIG. 4 structure 15A) turned on at lower current, while the narrow PN junction (FIG. 4 structure 15B) turned on at higher current.

Likewise, for the device structure with three cell designs, the widest PN junction is first turned on, then the PN junction with medium width, and finally the narrowest PN junction is turned on. For the device structure with four cell designs, the widest PN junction is first turned on, and the second PN junction, the third PN junction at even higher current, and the narrowest PN junction is the last one to be turned on. Through this design, the active area can be utilized more efficiently, and the current can be evenly dispersed in the whole area of the device, thereby effectively avoiding device damage caused by localized heating and improving device surge current capability.

In another aspect, a method for manufacturing a merged PiN Schottky (MPS) diode may include steps of providing a substrate having a first conductivity type; forming an epitaxial layer with the first conductivity type on top of the substrate; forming a plurality of regions with a second conductivity type under a top surface of the epitaxial layer; depositing and patterning a first Ohmic contact metal on the regions with the second conductivity type; depositing a Schottky contact metal on top of the entire epitaxial layer; and forming a second Ohmic contact metal on a backside of the substrate.

In one embodiment, the epitaxial layer is made of N-type silicon carbide. In another embodiment, the step of forming a plurality of regions with a second conductivity type under a top surface of the epitaxial layer may include steps of depositing and patterning a mask layer on the epitaxial layer, implanting P-type dopant into the epitaxial layer, and removing the mask layer. It is noted that the dopant can be aluminum or boron.

In a further embodiment, the step of depositing and patterning an Ohmic contact metal on the regions may include a step of annealing the Ohmic metal to enable the metal to be in direct contact with the epitaxial layer. In still a further embodiment, the step of depositing a Schottky contact metal on top of the entire epitaxial layer may include a step of conducting a low temperature annealing of the Schottky contact metal.

### BRIEF DESCRIPTION OF THE DRAWINGS

FIG. 1 is a cross-section view of the merged PiN Schottky (MPS) diode in the present invention.

FIG. 2 is a schematic view of a layout design of a merged PiN Schottky (MPS) diode with single size hexagonal cells.

FIG. 3 is a schematic view of a layout design of a merged PiN Schottky (MPS) diode with two different sizes of hexagonal cells.

FIG. 4 is the cross-section view of the merged PiN Schottky (MPS) diode with two different sizes of hexagonal cells along line EE′ in FIG. 3.

FIG. 5 is a schematic view of a layout design of a merged PiN Schottky (MPS) diode with three different sizes of hexagonal cells.

FIG. 6 is the cross-section view of the merged PiN Schottky (MPS) diode with three different sizes of hexagonal cells along line FF′ in FIG. 5.

FIG. 7 is the cross-section view of the merged PiN Schottky (MPS) diode with three different sizes of hexagonal cells along line GG′ in FIG. 5.

FIG. 8 is a schematic view of a layout design of a merged PiN Schottky (MPS) diode with four different sizes of hexagonal cells.

FIG. 9 is the cross-section view of the merged PiN Schottky (MPS) diode with four different sizes of hexagonal cells along line HH′ in FIG. 8.

FIG. 10 is the cross-section view of the merged PiN Schottky (MPS) diode with four different sizes of hexagonal cells along line II′ in FIG. 8.

FIGS. 11A to 11G illustrate a process flow of the method for manufacturing a merged PiN Schottky (MPS) diode in the present invention.

FIG. 12 is a block diagram illustrating the method for manufacturing a merged PiN Schottky (MPS) diode in the present invention.

### DETAILED DESCRIPTION OF THE INVENTION

The detailed description set forth below is intended as a description of the presently exemplary device provided in accordance with aspects of the present invention and is not intended to represent the only forms in which the present invention may be prepared or utilized. It is to be understood, rather, that the same or equivalent functions and components may be accomplished by different embodiments that are also intended to be encompassed within the spirit and scope of the invention.

Unless defined otherwise, all technical and scientific terms used herein have the same meaning as commonly understood to one of ordinary skill in the art to which this invention belongs. Although any methods, devices and materials similar or equivalent to those described can be used in the practice or testing of the invention, the exemplary methods, devices and materials are now described.

All publications mentioned are incorporated by reference for the purpose of describing and disclosing, for example, the designs and methodologies that are described in the publications that might be used in connection with the presently described invention. The publications listed or discussed above, below and throughout the text are provided solely for their disclosure prior to the filing date of the present application. Nothing herein is to be construed as an admission that the inventors are not entitled to antedate such disclosure by virtue of prior invention.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

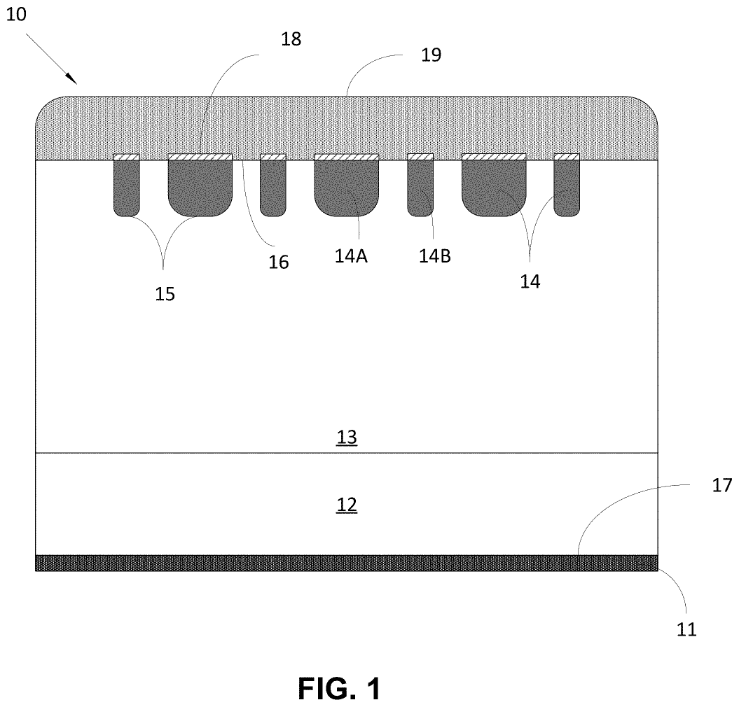

In one aspect as shown in FIG. 1, a merged PiN Schottky (MPS) diode 10 may include a silicon carbide substrate 12 having a first conductivity type, an epitaxial layer 13 with the first conductivity type formed on the substrate 12. In one embodiment, the doping concentration in the epitaxial layer 13 is lower than that in the substrate 12. The merged PiN Schottky (MPS) diode 10 may further include a plurality of regions 14 having a second conductivity type different from the first conductivity type, and formed under a top surface of the epitaxial layer 13.

A first Ohmic contact metal 18 is formed on top of each of the regions of the second conductivity type, and a Schottky contact metal 19 is placed on top of the entire epitaxial layer 13 to form a Schottky junction 16. A second Ohmic contact 17 is formed by a cathode electrode 11 on the back side of the substrate 12.

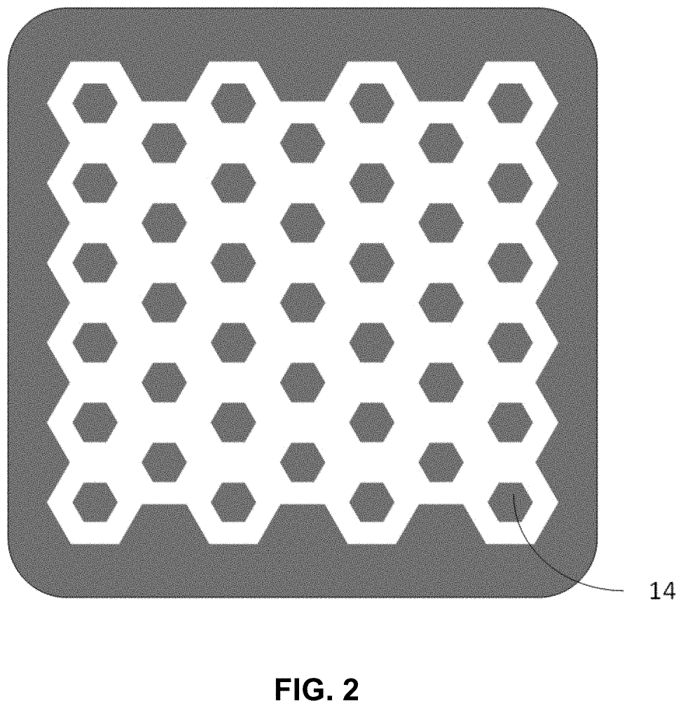

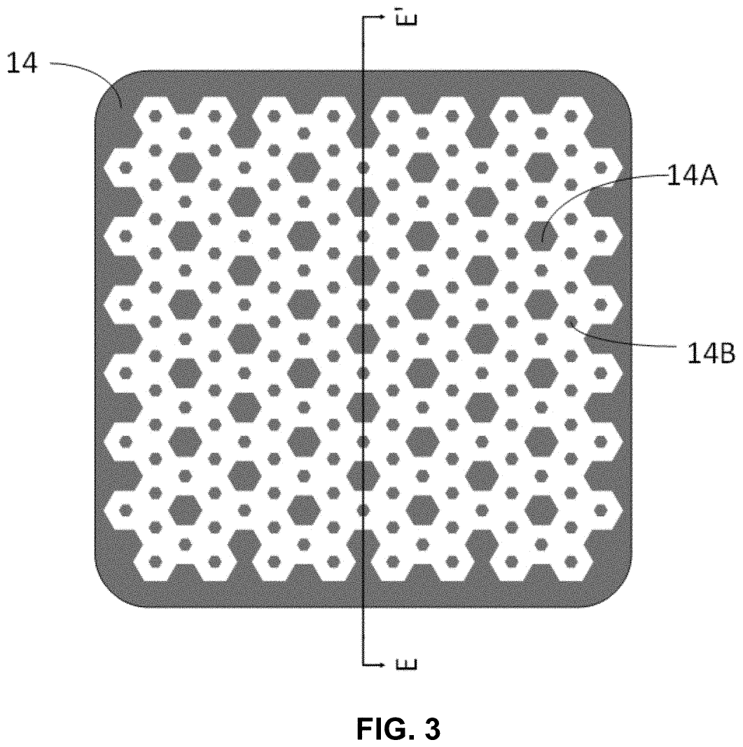

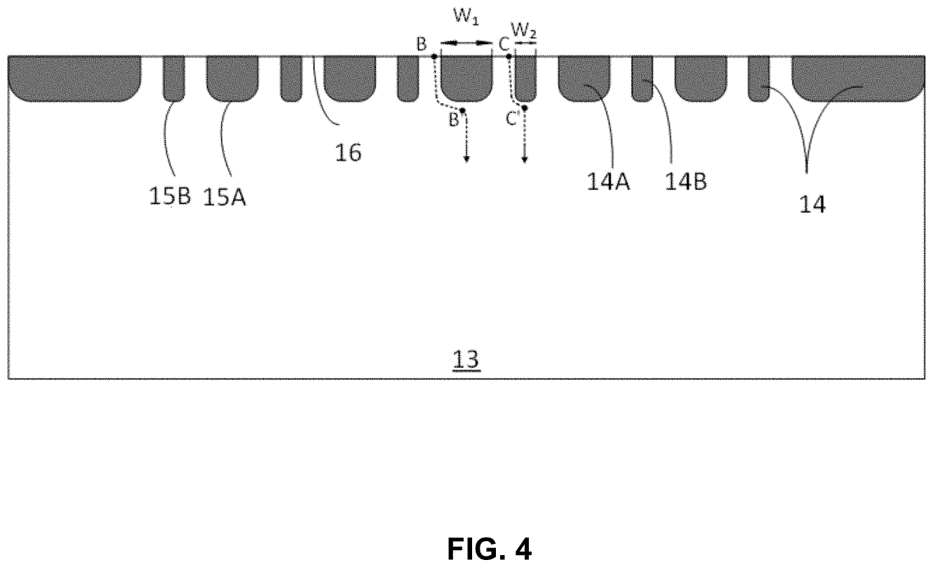

In one embodiment, the layout design of the merged PiN Schottky (MPS) diode can be a strip cell structure or hexagonal cell structure. In the present invention, the hexagonal cell structure design is used for illustrating examples as shown in FIG. 2. Based on the hexagonal cell structure, the design can be extended to a composite structure of multiple cells by adding hexagonal cells with different sizes. For example, FIGS. 3, 5, and 8 show designs with two, three, and four different hexagonal cells, respectively. The cross-section schematic view of the device structure of the two hexagonal cells design in FIG. 3 along AA′ is shown in FIG. 4, the widths of the two regions with the second conductivity type are denoted as W₁ and W₂, respectively.

When the diode is under forward bias, current flows from the anode of the diode through the Schottky junction 16 into a drift region 15, then through the substrate layer 12 and flows out of the cathode electrode 11. Before the current enters the drift region 15, it first passes through the channel region formed between the second conductivity type regions. Meanwhile, the current will form a potential difference on the PN junction, which is formed between the region with second conductivity type and the drift region with first conductivity type. When this potential difference exceeds the built-in potential of the PN junction, the PN junction will be turned on. Changing the width of the second conductivity type region will affect the threshold that triggers the turn-on of the PN junction. At the moment when the PN junction is turned on, the voltage drop between the anode and cathode of the diode is referred to as the PN junction turn-on voltage. The larger the width of the region 14 of the second conductivity type, the lower the PN junction turn-on voltage. This is because, as shown, the dash lines BB′, CC′ respectively show the current paths near the second conductivity type regions 14 with widths W₁ and W₂, respectively. When the potential difference between BB′ and CC′ reaches the built-in potential of the PN junction, the PN junction will be turned on. The potential difference between BB′ and CC′ is equal to the channel current times the resistance along the line BB′ and CC′, separately. It can be clearly seen from the figure that when the P+ region spacing is constant, the resistance of the channel is mainly affected by the width of the P+ region. If the width of the P+ region is larger (W₁ is greater than W₂), the resistance is larger (R_{BB′} is larger than R_{CC′}). Therefore, when the current increases to the threshold I₁ that triggers the first PN junction (FIG. 4, Structure 15A, formed by the P+ region with the width W₁), the potential difference between BB′ will reach the built-in potential of the PN junction, and the PN junction will be first turned on. As the current continues to increase and once the current is beyond the threshold I₂ at which the second PN junction is turned on, the potential difference between CC′ also reaches the built-in potential of the PN junction (FIG. 4, Structure 15B, formed by the P+ region of width W₂).

Based on the structure of the merged PiN Schottky (MPS) diode with the multiple cell proposed in this patent, the PN junction formed by different sizes of P+ regions are gradually turned on when the current exceeds the different corresponding threshold levels under the surge current. The electrical performance of the device under the surge current shock is closely related to the structure design. The device with two difference cells layout design as shown in FIG. 3, there are two different PN junctions, the wide PN junction (FIG. 4 structure 15A) is turned on at lower current, and the narrow PN junction (FIG. 4 structure 15B) is turned on at higher current.

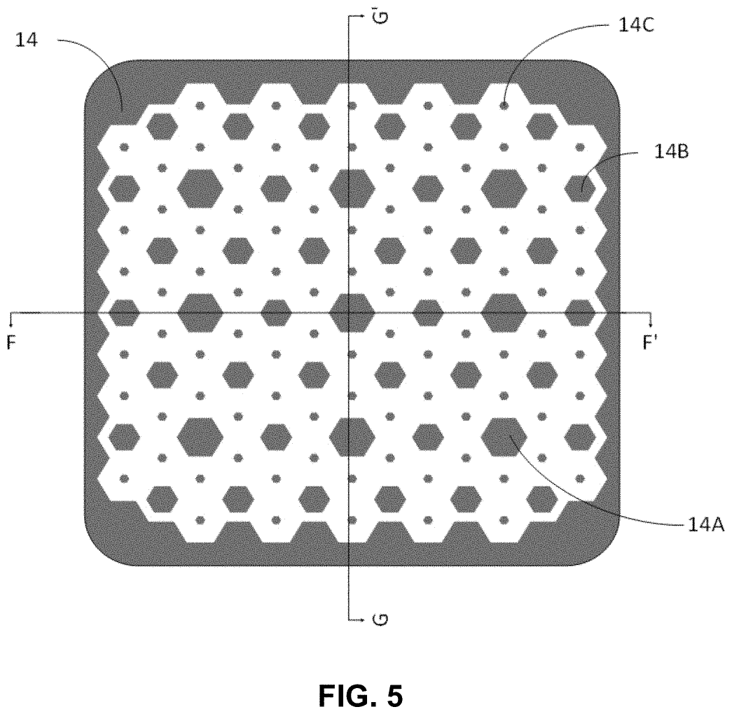

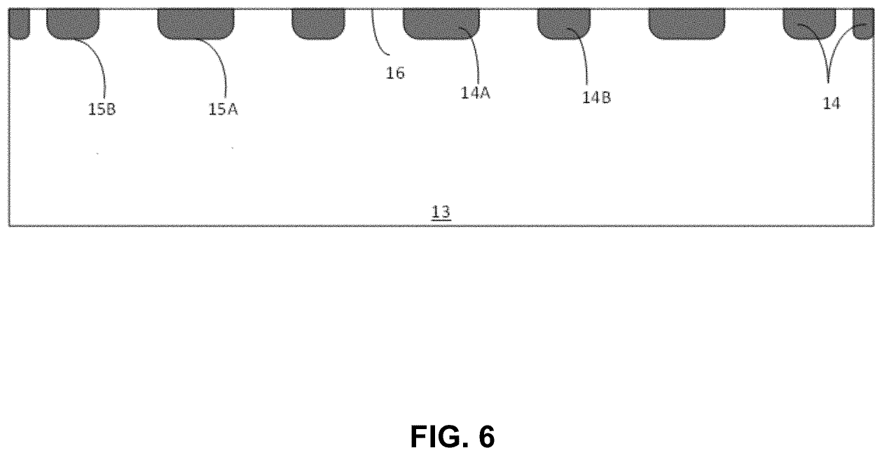

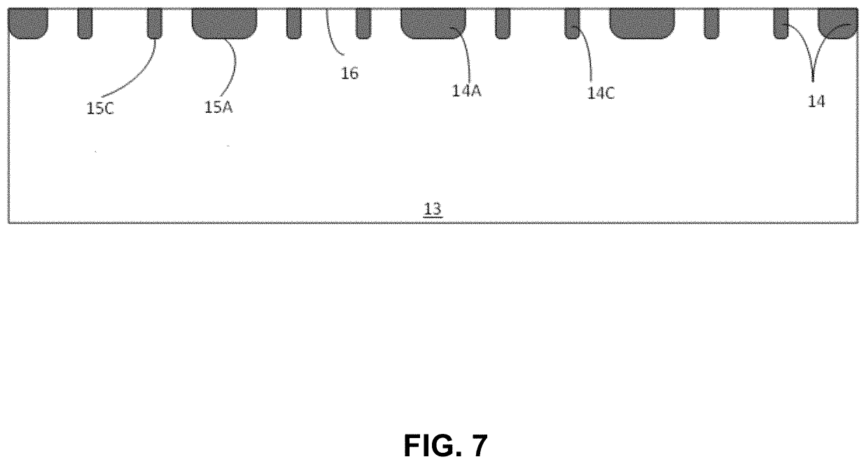

For the device structure with three cell designs as shown in FIG. 5, there are three different PN junctions, as current increasing, the widest PN junction (structure 15A in FIGS. 6 and 7) is first turned on, then the PN junction with medium width (structure 15B in FIG. 6) is turned on, finally the narrowest PN junction (structure 15C in FIG. 7) is turned on.

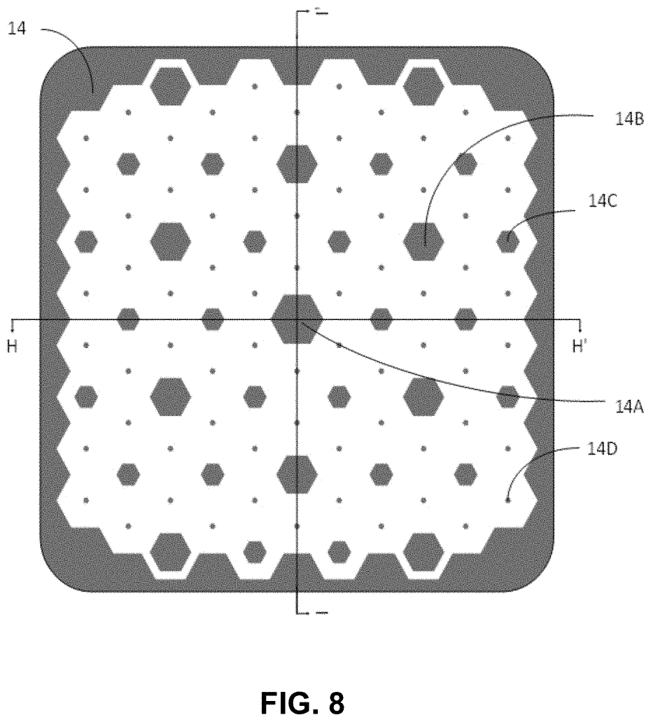

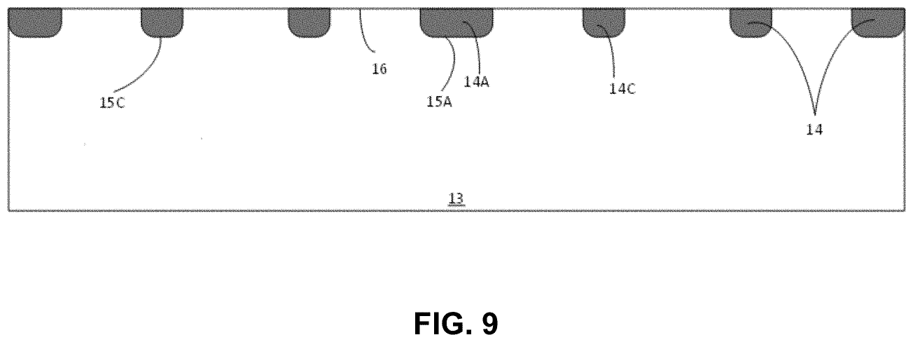

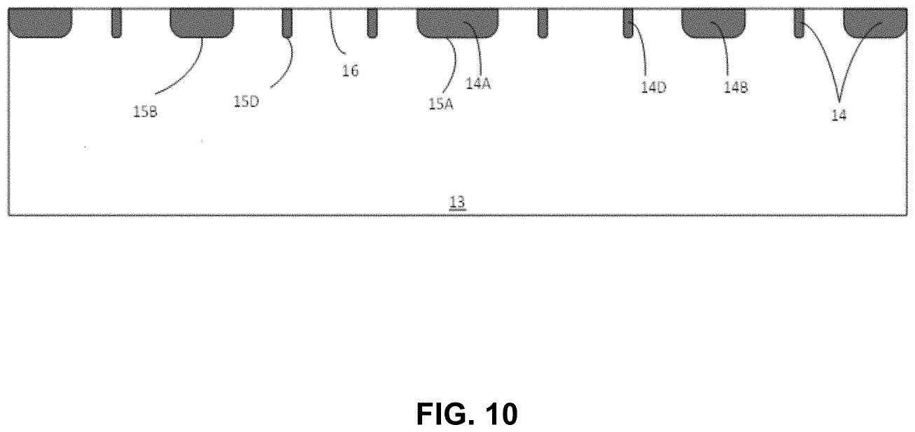

For the device structure with four cell designs shown in FIG. 8, there are four different PN junctions, the widest PN junction (structure 15A in FIGS. 9 and 10) is first turned on, and the second PN junction (structure 15B in FIG. 10) is turned on at higher current, the third PN junction (structure 15C in FIG. 9) is turned on at even higher current, and the narrowest PN junction (structure 15D in FIG. 10) is the last one to be turned on. Through this design, the active area can be utilized more efficiently, and the current can be evenly dispersed in the whole area of the device, thereby effectively avoiding device damage caused by localized heating and improving device surge current capability.

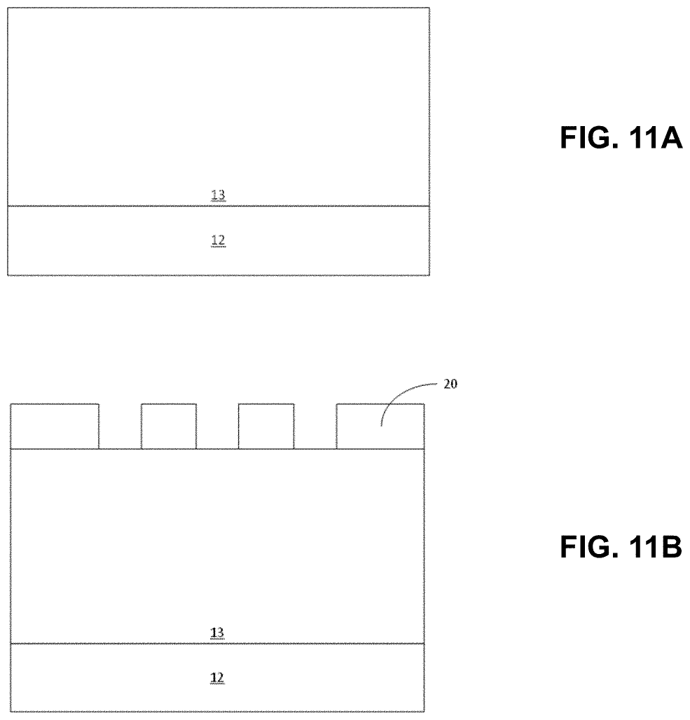

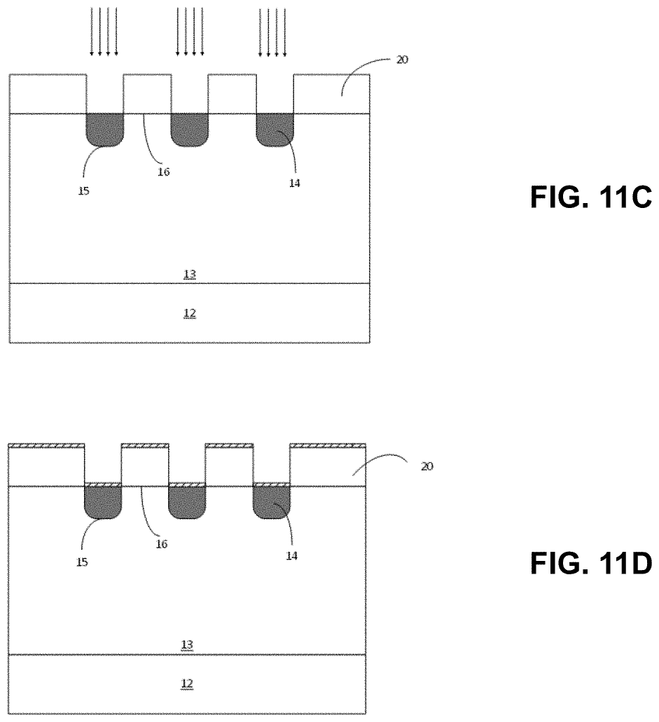

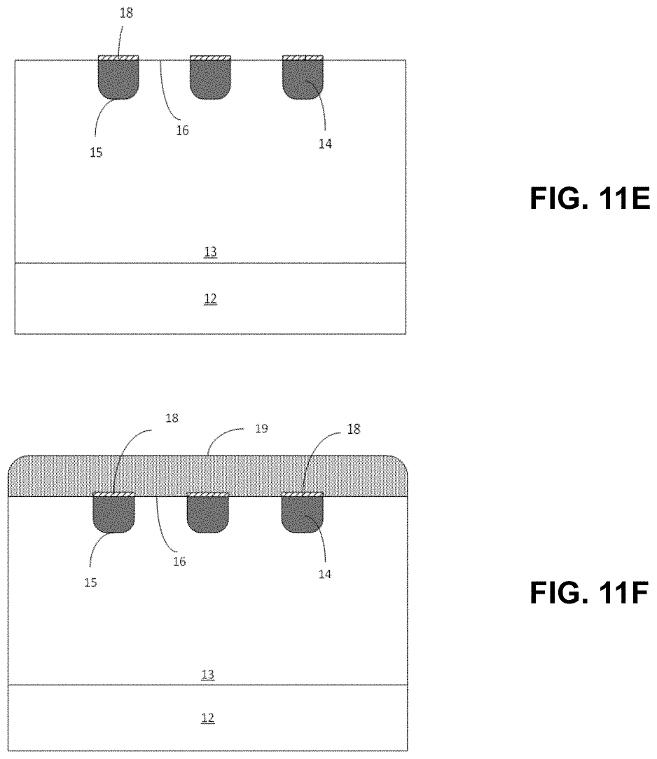

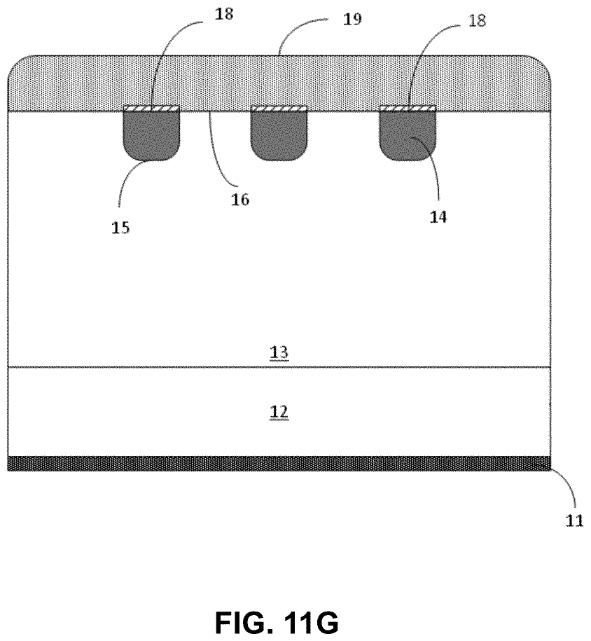

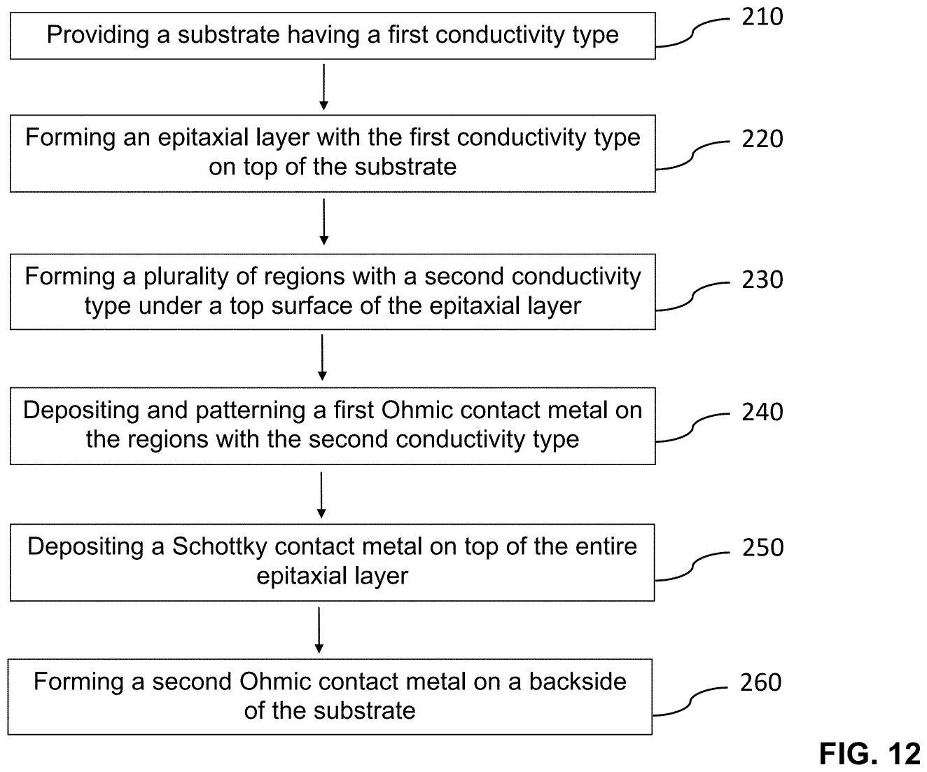

In another aspect, as shown in FIGS. 11A to 11G, a method for manufacturing a merged PiN Schottky (MPS) diode may include steps of providing a substrate having a first conductivity type 210; forming an epitaxial layer with the first conductivity type on top of the substrate 220; forming a plurality of regions with a second conductivity type under a top surface of the epitaxial layer 230; depositing and patterning a first Ohmic contact metal on the regions with the second conductivity type 240; depositing a Schottky contact metal on top of the entire epitaxial layer 250; and forming a second Ohmic contact metal on a backside of the substrate 260.

In one embodiment, the epitaxial layer is made of N-type silicon carbide. In another embodiment, the step of forming a plurality of regions with a second conductivity type under a top surface of the epitaxial layer 230 may include steps of depositing and patterning a mask layer 20 on the epitaxial layer 2301, implanting P-type dopant into the epitaxial layer 2302, and removing the mask layer 2303. It is noted that the dopant can be aluminum or boron.

In a further embodiment, the step of depositing and patterning a first Ohmic contact metal on the regions 240 may include a step of annealing the Ohmic metal to enable the metal to be in direct contact with the epitaxial layer. In still a further embodiment, the step of depositing a Schottky contact metal on top of the entire epitaxial layer 250 may include a step of conducting a low temperature annealing of the Schottky contact metal.

Having described the invention by the description and illustrations above, it should be understood that these are exemplary of the invention and are not to be considered as limiting. Accordingly, the invention is not to be considered as limited by the foregoing description, but includes any equivalent.

What is claimed is:

1. A method for manufacturing a merged PiN Schottky (MPS) diode comprising steps of:
providing a substrate having a first conductivity type;
forming an epitaxial layer with the first conductivity type on top of the substrate; forming a plurality of regions with a second conductivity type under a top surface of the epitaxial layer;
depositing and patterning a first Ohmic contact metal on the regions with the second conductivity type;
depositing a Schottky contact metal on top of the entire epitaxial layer; and
forming a second Ohmic contact metal on a backside of the substrate,
wherein a junction is formed between each region with second conductivity type and a drift region with first conductivity type, and a threshold potential to turn on the junction is determined by a width of each region.

2. The method for manufacturing a merged PiN Schottky (MPS) diode of claim 1, wherein the epitaxial layer is made of N-type silicon carbide, and the first conductivity type is P-type.

3. The method for manufacturing a merged PiN Schottky (MPS) diode of claim 1, wherein the step of forming a plurality of regions with a second conductivity type under a top surface of the epitaxial layer may include steps of depositing and patterning a mask layer on the epitaxial layer, implanting P-type dopants into the epitaxial layer, and removing the mask layer.

4. The method for manufacturing a merged PiN Schottky (MPS) diode of claim 3, wherein the dopant is aluminum or boron.

5. The method for manufacturing a merged PiN Schottky (MPS) diode of claim 1, wherein the step of depositing and patterning a first Ohmic contact metal on the regions includes a step of annealing the first Ohmic metal to enable the metal to directly contact with the epitaxial layer.

6. The method for manufacturing a merged PiN Schottky (MPS) diode of claim 1, wherein the step of depositing a Schottky contact metal on top of the entire epitaxial layer includes a step of conducting a low temperature annealing of the Schottky contact metal.

7. The method for manufacturing a merged PiN Schottky (MPS) diode of claim 2, wherein the junction formed between each P-type region and the N-type drift region is a PN junction.

8. A semiconductor device comprising:
a substrate having a first conductivity type;
an epitaxial layer having the first conductivity type deposited on one side of the substrate;
a plurality of regions having a second conductivity type formed under a top surface of the epitaxial layer;
a first Ohmic metal patterned and deposited on top of the regions with the second conductivity type;
a Schottky contact metal deposited on top of the entire epitaxial layer to form a Schottky junction; and
a second Ohmic metal deposited on a backside of the substrate,
wherein a junction is formed between each region with second conductivity type and a drift region with first conductivity type, and a threshold potential to turn on the junction is determined by a width of each region.

9. The semiconductor device of claim 8, wherein the epitaxial layer is made of N-type silicon carbide, and the first conductivity type is P-type.

10. The semiconductor device of claim 8, wherein the semiconductor device is a merged PiN Schottky (MPS) diode.

11. The semiconductor device of claim 9, wherein the junction formed between each P-type region and the N-type drift region is a PN junction, and the region with a greatest width is first to be turned on.
